(19) United States
(12) Patent Application Publication
(10) Pub. No.: US 2024/0379542 A1
(43) Pub. Date: Nov. 14, 2024

(54) SEMICONDUCTOR DEVICE HAVING RESISTANCE UNITS

(71) Applicant: MICRON TECHNOLOGY, INC., BOISE, ID (US)

(72) Inventors: Takanari Shimizu, Sagamihara (JP); Kiyotaka Endo, Tokyo (JP); Mitsuki Koda, Sagamihara (JP)

(73) Assignee: MICRON TECHNOLOGY, INC., Boise, ID (US)

(21) Appl. No.: 18/635,917

(22) Filed: Apr. 15, 2024

Related U.S. Application Data
(60) Provisional application No. 63/501,579, filed on May 11, 2023.

(51) Int. Cl. H01L 23/522

(52) U.S. Cl. CPC H01L 23/5228

(57) ABSTRACT

An example apparatus that includes a plurality of resistance units connected to one another, each of the plurality of resistance units including first and second conductive elements in a first layer, a third conductive element in a second layer, one or more first contact plugs between the first conductive element and the third conductive element and one or more second contact plugs between the second conductive element and the third conductive element, wherein number of first and second contact plugs is different among at least some of the plurality of resistance units.

### CROSS-REFERENCE TO RELATED APPLICATIONS

This application claims priority to U.S. Provisional Application No. 63/501,579, filed May 11, 2023. The aforementioned application is incorporated herein by reference, in its entirety, for any purpose.

### BACKGROUND

There is a case where a semiconductor device such as a DRAM (Dynamic Random Access Memory) includes a plurality of resistance units using high-resistance wiring layers. Connecting relations among the resistance units are switched according to the mask used at the time of manufacturing the semiconductor device, thereby realizing a desired resistance value. However, when it is configured to realize many resistance values, the number of required resistance units becomes larger and this leads to an increase in occupied area on a chip.

### BRIEF DESCRIPTION OF THE DRAWINGS

FIG. 1A is a schematic plan view showing a configuration of a resistance unit according to an embodiment of the present disclosure, and FIG. 1B is a schematic cross-sectional view along a line B-B shown in FIG. 1A;

FIGS. 2A to 2F are diagrams respectively showing an example where some contact plugs included in a resistance unit are omitted;

FIGS. 3A to 3C are diagrams respectively showing an example where three resistance units are connected to one another;

FIG. 4A is a schematic plan view showing a configuration of a resistance unit according to a first modification, and FIG. 4B is a schematic cross-sectional view along a line B-B shown in FIG. 4A; and

FIG. 5 is a schematic cross-sectional view showing a configuration of a resistance unit according to a second modification.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

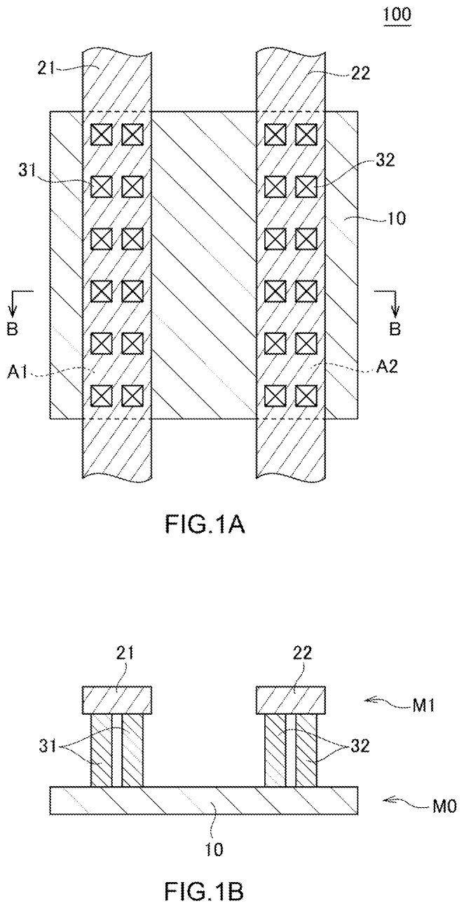

FIG. 1A is a schematic plan view showing a configuration of a resistance unit 100 according to an embodiment of the present disclosure. FIG. 1B is a schematic cross-sectional view along a line B-B shown in FIG. 1A. As shown in FIGS. 1A and 1B, the resistance unit 100 includes a wiring pattern 10 provided on a wiring layer M0 positioned on a lower layer, wiring patterns 21 and 22 provided on a wiring layer M1 positioned on an upper layer, a plurality of contact plugs 31 connecting the wiring pattern 10 and the wiring pattern 21, and a plurality of contact plugs 32 connecting the wiring pattern 10 and the wiring pattern 22. The wiring layer M1 is made of a low-resistance metallic material such as aluminum. The wiring layer M0 is made of a metallic material such as tungsten having a higher resistance value per unit sectional area than that of the metallic material forming the wiring layer M1. The wiring layer M0 may be a diffusion layer wire provided on a semiconductor substrate. The wiring pattern 10 and the wiring pattern 21 overlap each other in an area A1 and the plurality of contact plugs 31 are provided in the area A1. The wiring pattern 10 and the wiring pattern 22 overlap each other in an area A2 and the plurality of contact plugs 32 are provided in the area A2. The area size of the area A1 and the area size of the area A2 may be mutually the same.

The resistance value of the resistance unit 100, that is, the resistance value between the wiring pattern 21 and the wiring pattern 22 is determined by the sum of the resistance value of the wiring pattern 10, the combined resistance value of the plurality of contact plugs 31, and the combined resistance value of the plurality of contact plugs 32. In the semiconductor device according to the present disclosure, the resistance value of the resistance unit 100 is made variable by switching the numbers of the contact plugs 31 and 32 according to the mask used at the time of manufacturing the semiconductor device. In the example shown in FIG. 1A, 12 contact plugs 31 are provided in the area A1 and 12 contact plugs 32 are provided in the area A2. The sizes of respective contact plugs 31 and 32 are mutually the same. In the example shown in FIG. 1A, when the resistance value of the wiring pattern 10 is R10 and the resistance value of each of the contact plugs 31 and 32 is 90Ω, the resistance value of the resistance unit 100 is represented by R10+15Ω.

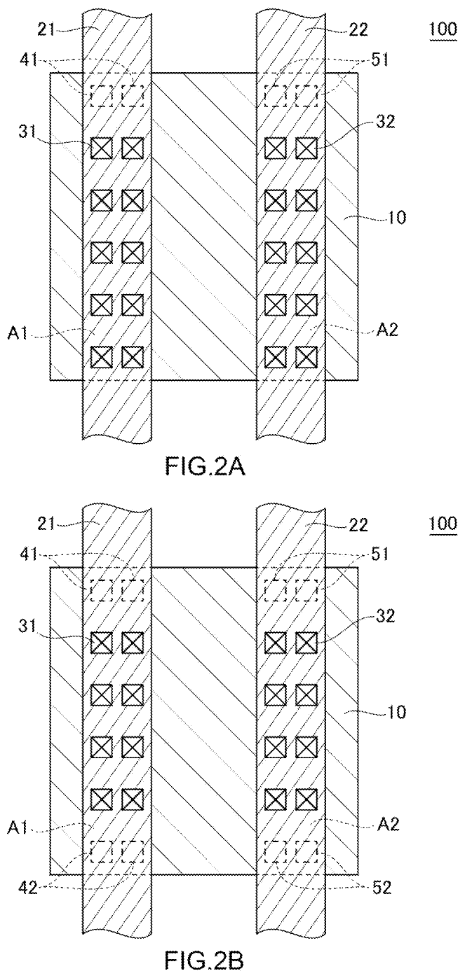

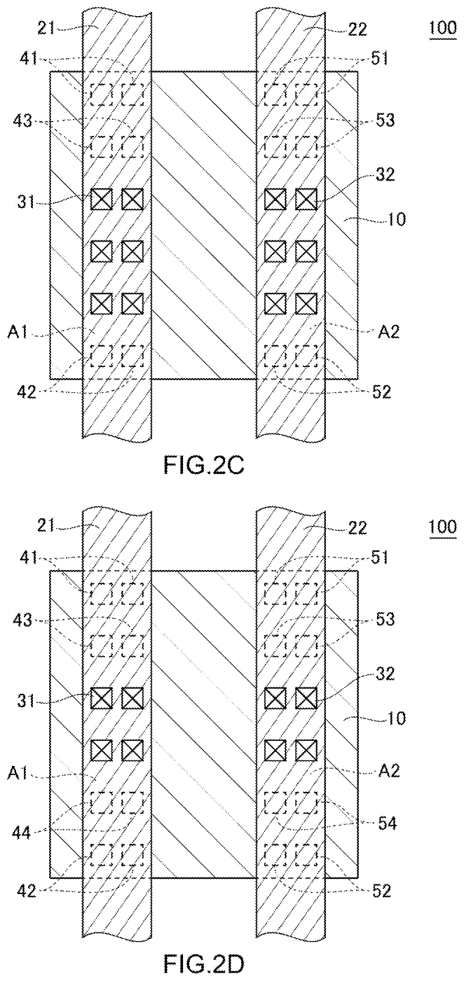

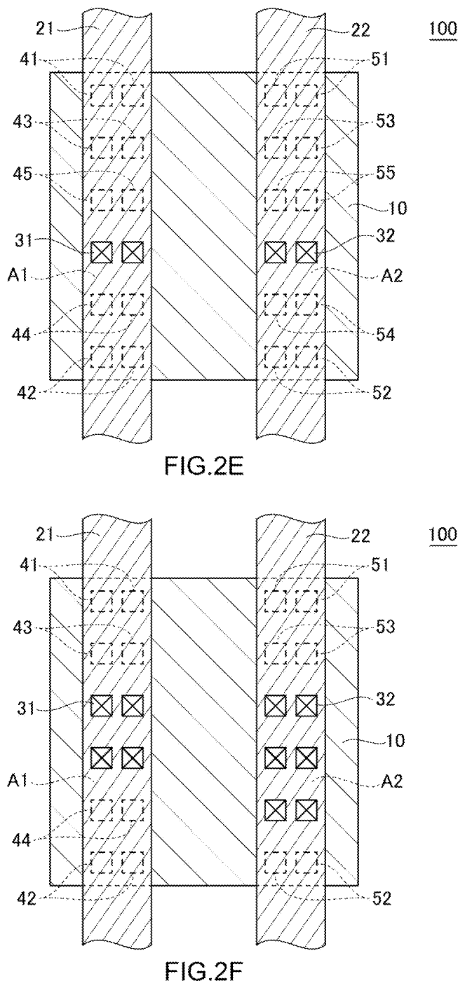

Meanwhile, as shown in FIG. 2A, when two contact plugs 31 are omitted from contact plug areas 41 in the area A1 and two contact plugs 32 are omitted from contact plug areas 51 in the area A2, each of the numbers of the contact plugs 31 and 32 respectively provided in the areas A1 and A2 becomes ten. In this case, the resistance value of the resistance unit 100 changes to R10+18Ω. As shown in FIG. 2B, when four contact plugs 31 are omitted from the contact plug areas 41 and contact plug areas 42 in the area A1 and four contact plugs 32 are omitted from the contact plug areas 51 and contact plug areas 52 in the area A2, each of the numbers of the contact plugs 31 and 32 respectively provided in the areas A1 and A2 becomes eight. In this case, the resistance value of the resistance unit 100 changes to R10+22.5Ω. As shown in FIG. 2C, when six contact plugs 31 are omitted from the contact plug areas 41 and 42 and contact plug areas 43 in the area A1 and six contact plugs 32 are omitted from the contact plug areas 51 and 52 and contact plug areas 53 in the area A2, each of the numbers of the contact plugs 31 and 32 respectively provided in the areas A1 and A2 becomes six. In this case, the resistance value of the resistance unit 100 changes to R10+30Ω. As shown in FIG. 2D, when eight contact plugs 31 are omitted from the contact plug areas 41 to 43 and contact plug areas 44 in the area A1 and eight contact plugs 32 are omitted from the contact plug areas 51 to 53 and contact plug areas 54 in the area A2, each of the numbers of the contact plugs 31 and 32 respectively provided in the areas A1 and A2 becomes four. In this case, the resistance value of the resistance unit 100 changes to R10+45Ω. As shown in FIG. 2E, when ten contact plugs 31 are omitted from the contact plug areas 41 to 44 and contact plug areas 45 in the area A1 and ten contact plugs 32 area are omitted from the contact plug areas 51 to 54 and contact plug areas 55 in the area A2, each of the numbers of the contact plugs 31 and 32 respectively provided in the areas A1 and A2 becomes two. In this case, the resistance value of the resistance unit 100 changes to R10+90Ω.

In this manner, by switching the mask and changing the numbers of the contact plugs 31 and 32, the resistance value of a single resistance unit 100 can be set in a varied manner. Accordingly, as compared to a method of changing the resistance value of the entire device by switching the connecting relation among a plurality of resistance units, the present disclosure can reduce an occupied area on a chip. Further, the number of the contact plugs 31 provided in the area A1 and the number of the contact plugs 32 provide in the area A2 do not need to be mutually the same, and as shown in FIG. 2F, these numbers may be different. In the example shown in FIG. 2F, eight contact plugs 31 are omitted from the contact plug areas 41 to 44 in the area A1 and six contact plugs 32 are omitted from the contact plug areas 51 to 53 in the area A2. Accordingly, the number of the contact plugs 31 provided in the area A1 becomes four and the number of the contact plugs 32 provided in the area A2 becomes six. In this case, the resistance value of the resistance unit 100 becomes R10+37.5Ω.

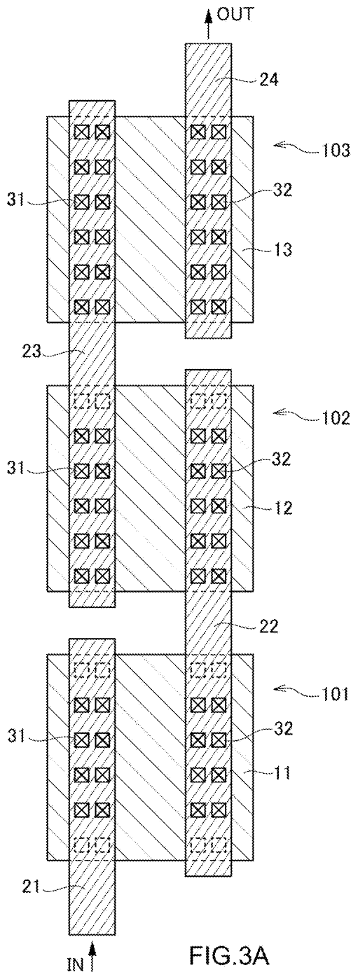

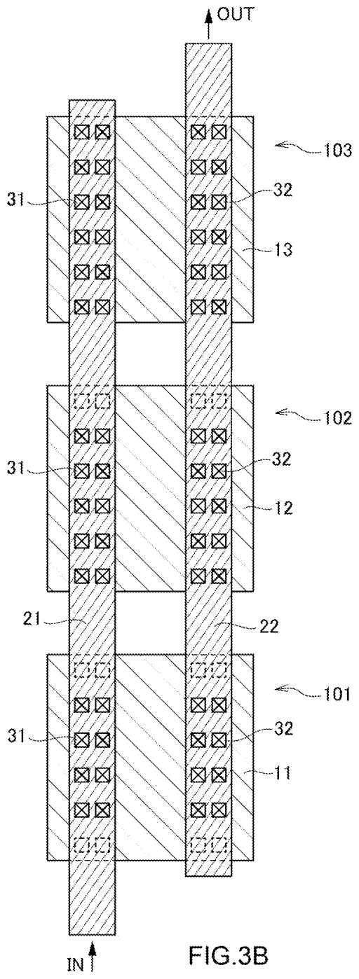

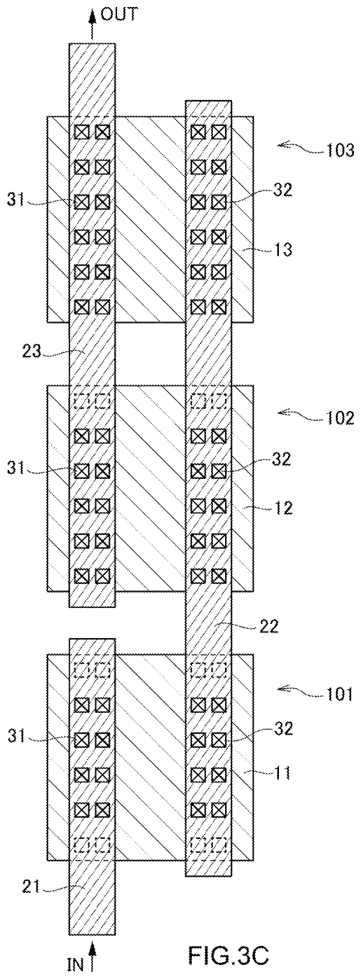

FIG. 3A is a diagram showing an example where three resistance units 101 to 103 are connected to one another in series. Each of the resistance units 101 to 103 has a configuration same as that of the resistance unit 100 shown in FIGS. 1A and 1B. Accordingly, the shape and size of wiring patterns 11 to 13 respectively included in the resistance units 101 to 103 are mutually the same and the shape and size of the areas A1 and A2 in the resistance units 101 to 103 are also mutually the same.

In the example shown in FIG. 3A, the numbers of the contact plugs 31 and 32 included in the resistance unit 101 are both eight, the numbers of the contact plugs 31 and 32 included in the resistance unit 102 are both ten, and the numbers of the contact plugs 31 and 32 included in the resistance unit 103 are both twelve. Therefore, the resistance values of the resistance units 101 to 103 are mutually different. In the example shown in FIG. 3A, the wiring pattern 21 connected to the contact plugs 31 of the resistance unit 101 forms an input node. The contact plugs 32 of the resistance unit 101 and the contact plugs 32 of the resistance unit 102 are connected to each other via the wiring pattern 22. The contact plugs 31 of the resistance unit 102 and the contact plugs 31 of the resistance unit 103 are connected to each other via a wiring pattern 23. A wiring pattern 24 connected to the contact plugs 32 of the resistance unit 103 forms an output node. In this manner, by connecting a plurality of resistance units having mutually different resistance values to one another in series, the resistance value of the entire device can be adjusted more finely.

FIG. 3B is a diagram showing an example where the three resistance units 101 to 103 are connected to one another in parallel. The numbers of the contact plugs 31 and 32 respectively included in the resistance units 101 to 103 are the same as those in FIG. 3A. That is, the resistance values of the resistance units 101 to 103 are mutually different. In the example shown in FIG. 3B, the wiring pattern 21 forming an input node is commonly connected to the contact plugs 31 of the resistance units 101 to 103, and the wiring pattern 22 forming an output node is commonly connected to the contact plugs 32 of the resistance units 101 to 103. In this manner, by connecting a plurality of resistance units having mutually different resistance values to one another in parallel, the resistance value of the entire device can be adjusted more finely.

In the example shown in FIG. 3C, the wiring pattern 21 connected to the contact plugs 31 of the resistance unit 101 forms an input node. The wiring pattern 22 is commonly connected to the contact plugs 32 of the resistance units 101 to 103. The wiring pattern 23 forming an output node is commonly connected to the contact plugs 31 of the resistance units 102 and 103. In this manner, by connecting some of a plurality of resistance units having mutually different values to one another in series and connecting the rest of the resistance units to one another in parallel, the resistance value of the entire device can be adjusted more finely.

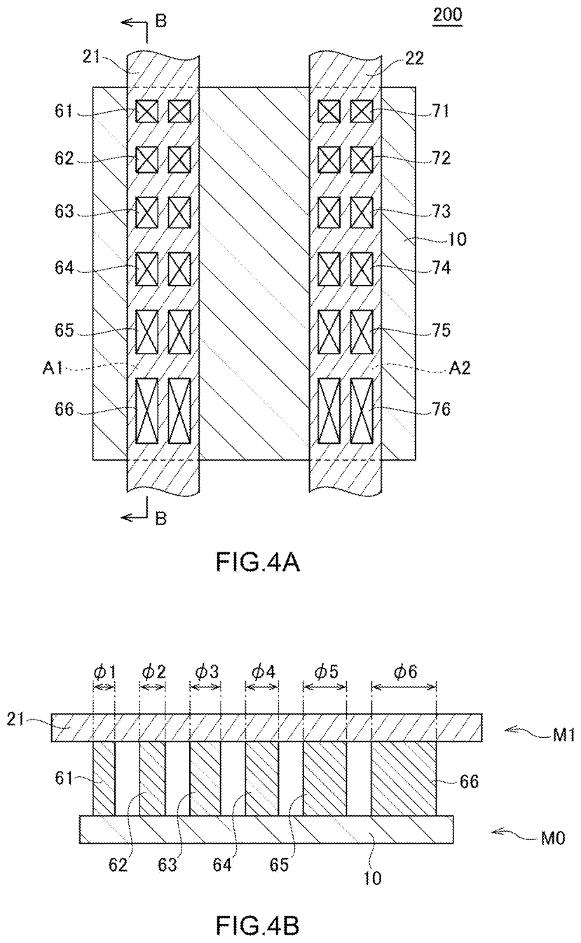

FIG. 4A is a schematic plan view showing a configuration of a resistance unit 200 according to a first modification. FIG. 4B is a schematic cross-sectional view along a line B-B shown in FIG. 4A. As shown in FIGS. 4A and 4B, in the resistance unit 200, the wiring pattern 10 and the wiring pattern 21 are connected to each other via a plurality of contact plugs 61 to 66 and the wiring pattern 10 and the wiring pattern 22 are connected to each other via a plurality of contact plugs 71 to 76. The diameters of the contact plugs 61 to 66 are φ1 to φ6, respectively. The diameters of the contact plugs 61 to 66 are mutually different and are set to be φ1<φ2<φ3<φ4<φ5<φ6. The diameters of the contact plugs 71 to 76 are respectively the same as those of the contact plugs 61 to 66. By switching the mask, as some of the contact plugs 61 to 66 and 71 to 76 are omitted, the resistance value of the resistance unit 200 is changed. Further, since the diameters of the contact plugs 61 to 66 as well as the diameters of the contact plugs 71 to 76 are mutually different, the resistance values of the contact plugs 61 to 66 are mutually different and the resistance values of the contact plugs 71 to 76 are also mutually different. Therefore, by appropriately selecting contact plugs to be omitted, the resistance value of the resistance unit 200 can be adjusted more finely.

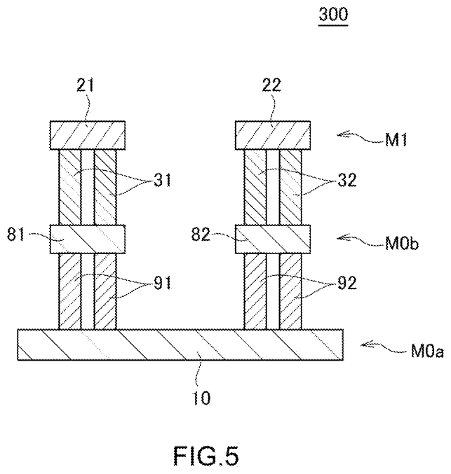

FIG. 5 is a schematic cross-sectional view showing a configuration of a resistance unit 300 according to a second modification. As shown in FIG. 5, in the resistance unit 300, the wiring layer M0 is divided into two wiring layers M0a and M0b. Each of the wiring layers M0a and M0b is made of a high-resistance metallic material such as tungsten. On the wiring layer M0b, a wiring pattern 81 is provided in a position overlapping both the wiring patterns 10 and 21 and a wiring pattern 82 is provided in a position overlapping both the wiring patterns 10 and 22. The wiring pattern 21 and the wiring pattern 81 are connected to each other via a plurality of contact plugs 31 and the wiring pattern 81 and the wiring pattern 10 are connected to each other via a plurality of contact plugs 91. The wiring pattern 22 and the wiring pattern 82 are connected to each other via a plurality of contact plugs 32 and the wiring pattern 82 and the wiring pattern 10 are connected to each other via a plurality of contact plugs 92. Also in the resistance unit 300 having such a configuration, by omitting some of the contact plugs 31, 32, 91, and 92, the resistance value of the entire device can be changed. Further, in the resistance unit 300, since the number of providable contact plugs per unit area is large, the resistance value of the resistance unit 300 can be adjusted more finely while suppressing an increase in occupied area on a chip.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a plurality of resistance units connected to one another, each of the plurality of resistance units including first and second conductive elements in a first layer, a third conductive element in a second layer, one or more first contact plugs between the first conductive element and the third conductive element and one or more second contact plugs between the second conductive element and the third conductive element;
wherein a number of first and second contact plugs is different among at least some of the plurality of resistance units.

2. The apparatus of claim 1, wherein the plurality of resistance units are connected in series.

3. The apparatus of claim 1, wherein the plurality of resistance units are connected in parallel.

4. The apparatus of claim 1, wherein a resistance value of the third conductive element per unit sectional area is higher than a resistance value of the first and second conductive elements per unit sectional area.

5. The apparatus of claim 4, wherein the third conductive element is made of tungsten.

6. The apparatus of claim 1,
wherein the first layer is a wiring layer, and
wherein the second layer is a diffusion layer.

7. The apparatus of claim 1, wherein, in at least one of the plurality of resistance units, a number of first contact plugs is different from a number of second contact plugs.

8. The apparatus of claim 1, wherein a first one of the first contact plugs is different in size from a second one of the first contact plugs.

9. An apparatus comprising:
a first layer including first and second conductive elements having the same area size as each other;
a second layer including third, fourth, and fifth conductive elements;
a plurality of first contact plugs connected between the first and third conductive elements;
a plurality of second contact plugs connected between the first and fourth conductive elements;
a plurality of third contact plugs connected between the second and fourth conductive elements; and
a plurality of fourth contact plugs connected between the second and fifth conductive elements,
wherein a first region where the first and third conductive elements overlap has a first area size,
wherein a second region where the first and fourth conductive elements overlap has a second area size,
wherein a third region where the second and fourth conductive elements overlap has a third area size,
wherein a fourth region where the second and fifth conductive elements overlap has a fourth area size,
wherein the second area size is the same as the third area size, and
wherein a number of the second contact plugs is different from a number of the third contact plugs.

10. The apparatus of claim 9,
wherein the first area size is the same as the fourth area size, and
wherein a number of the first contact plugs is different from a number of the fourth contact plugs.

11. The apparatus of claim 10,
wherein the first area size is the same as the second area size, and
wherein the number of the first contact plugs is the same as the number of the second contact plugs.

12. The apparatus of claim 10, wherein the number of the first contact plugs is different from the number of the second contact plugs.

13. The apparatus of claim 9,
wherein the first layer further includes a sixth conductive element having the same area size as the each of the first and second conductive elements,
wherein the second layer further includes a seventh conductive element,
wherein the apparatus further comprises:
a plurality of fifth contact plugs connected between the sixth and fifth conductive elements; and
a plurality of sixth contact plugs connected between the sixth and seventh conductive elements,
wherein a fifth region where the sixth and fifth conductive elements overlap has a fifth area size,
wherein a sixth region where the sixth and seventh conductive elements overlap has a sixth area size,
wherein the fifth area size is the same as the fourth area size, and
wherein a number of the fourth contact plugs is different from a number of the fifth contact plugs

14. The apparatus of claim 13,
wherein the sixth area size is the same as the second area size, and
wherein a number of the sixth contact plugs is different from at least one of the number of the second and third contact plugs.

15. The apparatus of claim 14, wherein the number of the sixth contact plugs is different from each of the number of the second and third contact plugs.

16. The apparatus of claim 15,
wherein the fifth area size is the same as the first area size, and
wherein a number of the first contact plugs is different from each of the number of the fourth and fifth contact plugs.

17. The apparatus of claim 9,
wherein the first layer is a wiring layer, and
wherein the second layer is a diffusion layer.

18. An apparatus comprising:
a plurality of resistance units including first and second resistance units connected to each other, each of the plurality of resistance units including first and second conductive elements in a first layer, a third conductive element in a second layer, a first contact plug group between the first conductive element and the third conductive element and a second contact plug group between the second conductive element and the third conductive element,
wherein, in the first conductive element, first, second, and third contact plug regions are assigned,
wherein, in the second conductive element, fourth, fifth, and sixth contact plug regions are assigned,
wherein the first contact plug group of the first resistance unit includes first, second, and third contact plugs located at the first, second, and third contact plug regions, respectively,
wherein the second contact plug group of the first resistance unit includes fourth, fifth, and sixth contact plugs located at the fourth, fifth, and sixth contact plug regions, respectively,
wherein the first contact plug group of the second resistance unit includes seventh and eighth contact plugs located at the first and second contact plug regions, respectively,
wherein the second contact plug group of the second resistance unit includes ninth and tenth contact plugs located at the fourth and fifth contact plug regions, respectively,
wherein no contact plug is provided at the third contact plug region in the second resistance unit, and
wherein no contact plug is provided at the sixth contact plug region in the second resistance unit.

19. The apparatus of claim 18, wherein a number of the contact plugs included in the first and second contact plug groups of the first resistance unit is different from a number of the contact plugs included in the first and second contact plug groups of the second resistance unit.

20. The apparatus of claim 18, wherein a number of the contact plugs included in the first contact plug group of the first resistance unit is different from a number of the contact plugs included in the second contact plug group of the first resistance unit.
